(19) United States
(12) Patent Application Publication
(10) Pub. No.: US 2026/0201558 A1
(43) Pub. Date: Jul. 16, 2026

(54) WAFER PROCESSING EQUIPMENT

(71) Applicant: SAMSUNG ELECTRONICS CO., LTD., Suwon-si (KR)

(72) Inventors: Donghyun JANG, Suwon-si (KR); Giduck KWEON, Suwon-si (KR); Joonki KIM, Suwon-si (KR); Hyojoong KIM, Suwon-si (KR); Young-Joon AHN, Suwon-si (KR); Chang-Hak OH, Suwon-si (KR); Dae-Han YOON, Suwon-si (KR); Kyuchol LEE, Suwon-si (KR); Hyunju LEE, Suwon-si (KR)

(73) Assignee: SAMSUNG ELECTRONICS CO., LTD., Suwon-si (KR)

(21) Appl. No.: 19/264,170

(22) Filed: Jul. 9, 2025

(30) Foreign Application Priority Data
Jan. 15, 2025 (KR) 10-2025-0006145

(51) Int. Cl. C23C 16/455

(52) U.S. Cl. CPC C23C 16/45563; C23C 16/45544

(57) ABSTRACT

Provided is a wafer processing apparatus including a process chamber configured to include a plurality of wafers stacked in a first direction, and a gas nozzle included in the process chamber, the gas nozzle extending along the first direction, wherein the gas nozzle includes an alignment hole and a tilting hole, the alignment hole and the tilting hole being configured to face the plurality of wafers along the first direction based on the plurality of wafers being stacked in the process chamber in the first direction, wherein a central axis of the alignment hole is configured to pass through a central axis of the plurality of wafers based on the plurality of wafers being stacked in the process chamber in the first direction, and wherein a central axis of the tilting is configured to be misaligned with respect to the central axis of the plurality of wafers based on the plurality of wafers being stacked in the process chamber in the first direction.

### CROSS-REFERENCE TO RELATED APPLICATION

This application claims priority to Korean Patent Application No. 10-2025-0006145, filed on Jan. 15, 2025, in the Korean Intellectual Property Office, the disclosure of which is incorporated herein by reference in its entirety.

### BACKGROUND

### 1. Field

Embodiments of the present disclosure relate to a wafer processing apparatus.

### 2. Description of Related Art

Generally, a semiconductor manufacturing process includes a series of unit processes such as deposition process, photo-lithography process, etching process, and ion implantation process. Some unit processes (for example, deposition process and diffusion process) are performed in a vacuum process chamber, and for example, semiconductor wafer processing apparatus such as chemical vapor deposition apparatus, atomic layer deposition (ALD) apparatus, and diffusion furnace may be used.

Particularly, during the semiconductor diffusion process, an ALD process refers to a process in which a hole is positioned per a sheet of wafer on a gas nozzle within a process chamber, and a gas sprayed through the hole is deposited onto a wafer. In the deposition process, the amount of a gas sprayed from each hole is a significant element to determine thickness of a deposited layer of a wafer, and uniformity of the thickness of a deposited layer of a wafer should be maintained consistently.

### SUMMARY

One or more embodiments provide a wafer processing apparatus that improves wafer production per batch while consistently maintaining uniformity of thickness of a deposited layer of a wafer by applying an improved gas nozzle.

According to an aspect of one or more embodiments, there is provided a wafer processing apparatus including a process chamber configured to include a plurality of wafers stacked in a first direction, and a gas nozzle included in the process chamber, the gas nozzle extending along the first direction, wherein the gas nozzle includes an alignment hole and a tilting hole, the alignment hole and the tilting hole being configured to face the plurality of wafers along the first direction based on the plurality of wafers being stacked in the process chamber in the first direction, wherein a central axis of the alignment hole is configured to pass through a central axis of the plurality of wafers based on the plurality of wafers being stacked in the process chamber in the first direction, and wherein a central axis of the tilting is configured to be misaligned with respect to the central axis of the plurality of wafers based on the plurality of wafers being stacked in the process chamber in the first direction.

According to another aspect of one or more embodiments, there is provided a wafer processing apparatus, including a process chamber configured to include a plurality of wafers stacked in a first direction, a gas supply pipe configured to supply a reaction gas into the process chamber, and a gas nozzle included in the process chamber and extending along the first direction, the gas nozzle being configured to spray the plurality of wafers with the reaction gas supplied from the gas supply pipe based on the plurality of wafers being stacked in the process chamber in the first direction, wherein the gas nozzle includes an alignment part, a first tilting part, and a second tilting part, wherein the alignment part includes a plurality of alignment holes being configured to face the plurality of wafers along the first direction and respectively having a central axis configured to pass through a central axis of the plurality of wafers based on the plurality of wafers being stacked in the process chamber in the first direction, wherein the first tilting part includes a plurality of first tilting holes being configured to face the plurality of wafers along the first direction and respectively having a central axis being configured to be spaced apart from the central axis of the plurality of wafers based on the plurality of wafers being stacked in the process chamber in the first direction, and wherein the second tilting part is spaced apart from the first tilting part in the first direction and includes a plurality of second tilting holes being configured to face the plurality of wafers along the first direction and respectively having a central axis being configured to be spaced apart from the central axis of the plurality of wafers based on the plurality of wafers being stacked in the process chamber in the first direction.

According to still another aspect of one or more embodiments, there is provided a wafer processing apparatus including a process chamber configured to include a plurality of wafers stacked in a first direction, a gas supply pipe configured to supply a reaction gas into the process chamber, and a gas nozzle included in the process chamber and extending along the first direction, the gas nozzle being configured to spray the plurality of wafers with the reaction gas supplied from the gas supply pipe based on the plurality of wafers being stacked in the process chamber in the first direction, wherein the gas nozzle includes a first alignment part, a second alignment part, and a tilting part, wherein the first alignment part includes a plurality of first alignment holes being configured to face the plurality of wafers along the first direction and respectively having a central axis being configured to pass through a central axis of the plurality of wafers, wherein the second alignment part includes a plurality of second alignment holes being configured to face the plurality of wafers along the first direction and respectively having a central axis being configured to pass through the central axis of the plurality of wafers based on the plurality of wafers being stacked in the process chamber in the first direction, wherein the tilting part includes a plurality of tilting holes being configured to face the plurality of wafers along the first direction and respectively having a central axis being configured to be spaced apart from the central axis of the plurality of wafers based on the plurality of wafers being stacked in the process chamber in the first direction, and wherein the tilting part is between the first alignment part and the second alignment part along the first direction.

According to another aspect, there is provided a thin film deposition method using a wafer processing apparatus including stacking a plurality of wafers within a process chamber along a first direction, supplying a source gas through a gas nozzle including at least one or more alignment holes and at least one or more tilting holes, which are disposed at a position facing the plurality of wafers along the first direction within the process chamber, supplying a first purge gas within the process chamber, supplying a reaction gas within the process chamber through the gas nozzle, and supplying a second purge gas within the process chamber. A central axis of the at least one or more alignment holes passes through a central axis of the plurality of wafers and a central axis of the at least one or more tilting holes is misaligned with the central axis of the plurality of wafers.

### BRIEF DESCRIPTION OF DRAWINGS

These and/or other aspects, features, and advantages of the invention will become apparent and more readily appreciated from the following description of example embodiments, taken in conjunction with the accompanying drawings of which:

FIG. 1 is a schematic perspective view illustrating a wafer processing apparatus according to one or more embodiments;

FIG. 2 is a schematic cross-sectional view illustrating a wafer processing apparatus according to one or more embodiments;

FIG. 3 is an exemplary diagram illustrating a cross section taken along A-A′ line in FIG. 2;

FIG. 4 is a schematic diagram illustrating a gas nozzle according to one or more embodiments;

FIG. 5 is a schematic view for explaining an alignment relation between the gas nozzle illustrated in FIG. 4 and a wafer;

FIG. 6A is an exemplary diagram illustrating a cross section taken along B1-B1′ line in FIG. 4;

FIG. 6B is an exemplary diagram illustrating a cross section taken along B2-B2′ line in FIG. 4;

FIG. 6C is an exemplary diagram illustrating a cross section taken along B3-B3′ line in FIG. 4;

FIG. 7 is a schematic view for explaining an alignment relation between a gas nozzle and a wafer according to one or more other embodiments;

FIG. 8 is a schematic view for explaining an alignment relation between a gas nozzle and a wafer according to one or more other embodiments;

FIG. 9A is an exemplary diagram illustrating a cross section of the gas nozzle illustrated in FIG. 8 and a portion corresponding to a cross section of FIG. 6A;

FIG. 9B is an exemplary diagram illustrating a cross section of the gas nozzle illustrated in FIG. 8 and a portion corresponding to a cross section of FIG. 6B;

FIG. 9C is an exemplary diagram illustrating a cross section of the gas nozzle illustrated in FIG. 8 and a portion corresponding to a cross section of FIG. 6C;

FIG. 10 is a schematic view for explaining an alignment relation between a gas nozzle and a wafer according to one or more other embodiments;

FIG. 11 is a schematic diagram illustrating a gas nozzle according to one or more other embodiments;

FIG. 12 is a schematic view for explaining an alignment relation between the gas nozzle illustrated in FIG. 11 and a wafer;

FIG. 13 is a schematic view for explaining an alignment relation between a gas nozzle and a wafer according to one or more other embodiments;

FIG. 14 is a schematic view for explaining an alignment relation between a gas nozzle and a wafer according to one or more other embodiments;

FIG. 15 is a schematic view for explaining an alignment relation between a gas nozzle and a wafer according to one or more other embodiments;

FIG. 16 is a schematic diagram illustrating a gas nozzle according to one or more other embodiments;

FIG. 17 is a schematic diagram illustrating a gas nozzle according to one or more other embodiments;

FIG. 18A is an exemplary diagram illustrating a cross section taken along C1-C1′ line in FIG. 17;

FIG. 18B is an exemplary diagram illustrating a cross section taken along C2-C2′ line in FIG. 17;

FIG. 19 is a schematic diagram illustrating a gas nozzle according to one or more other embodiments;

FIG. 20 is a flowchart illustrating a thin film deposition method using a wafer processing apparatus according to one or more embodiments; and

FIGS. 21, 22, 23, 24, and 25 are cross-sectional views illustrated according to a process sequence for explaining a process of manufacturing a semiconductor device through a thin film deposition method using a wafer processing apparatus according to one or more embodiments.

### DETAILED DESCRIPTION

Hereinafter, embodiments of the present disclosure are described in detail with reference to the accompanying drawings. Identical reference signs are used for identical elements in the drawings, and a repeated explanation therefor is omitted. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

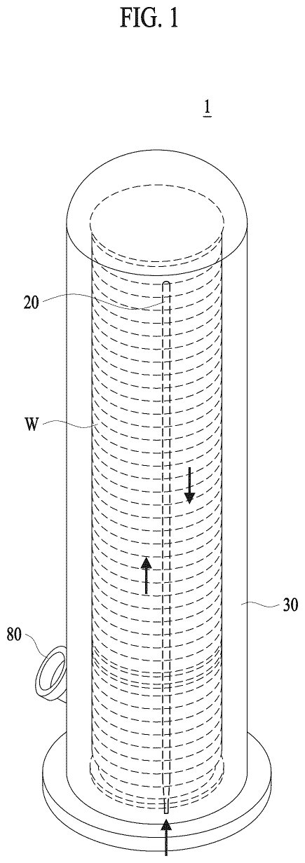

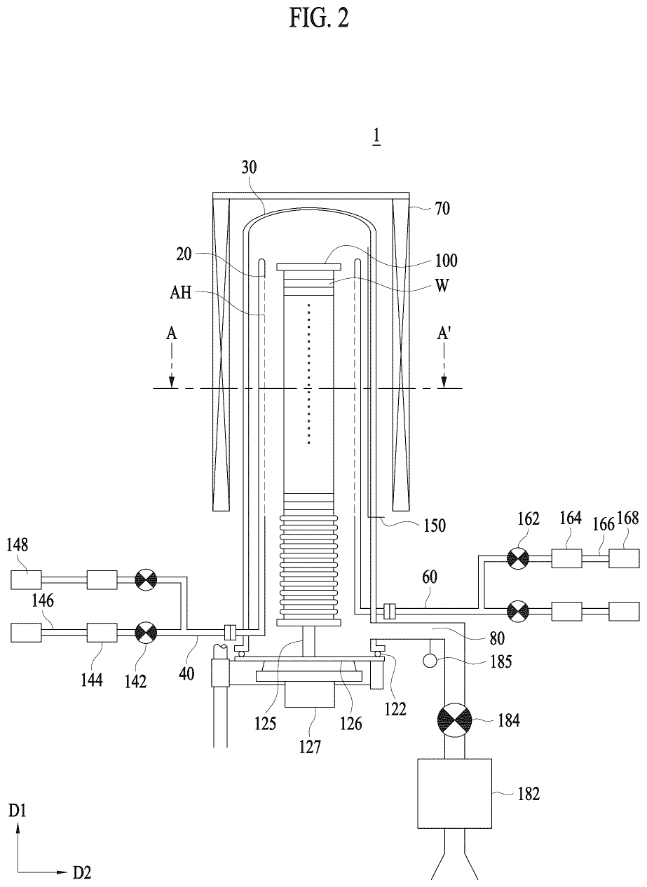

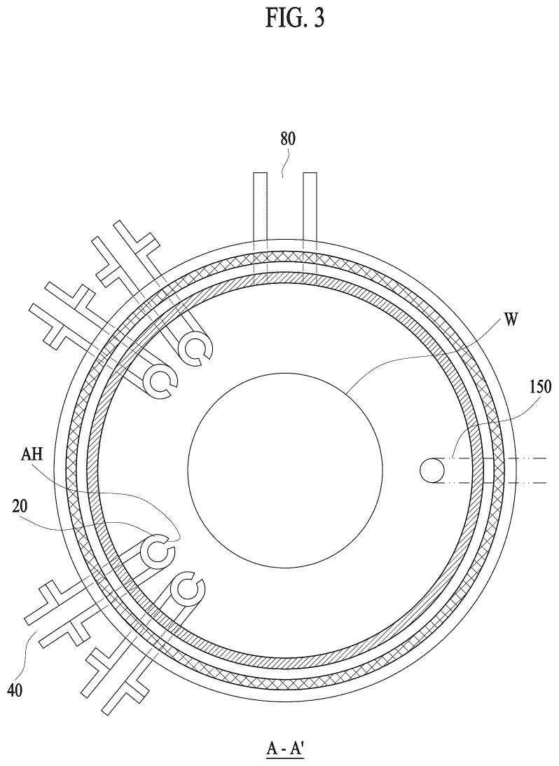

FIG. 1 is a schematic perspective view illustrating a wafer processing apparatus 1 according to one or more embodiments, and FIG. 2 is a schematic cross-sectional view illustrating the wafer processing apparatus 1 according to one or more embodiments, and FIG. 3 is an exemplary diagram illustrating a cross section taken along A-A′ line in FIG. 2.

Referring to FIGS. 1 to 3, the wafer processing apparatus 1 may include a gas nozzle 20, a process chamber 30, and gas supply pipes 40 and 60. A plurality of wafers W may be stacked within the process chamber 30 of the wafer processing apparatus 1. The process chamber 30 may include a heat-resistant material such as, for example, quartz (SiO₂) and silicon (Si) and have a cylinder form where a top is closed and an opening is formed on a bottom. The bottom of the process chamber 30 may be sealed by contacting a seal cap 126, and an O-ring 122 may be installed as a sealing member between the process chamber 30 and the seal cap 126. The O-ring 122 may be manufactured from a soft material such as, for example, rubber or teflon and have a discus shape.

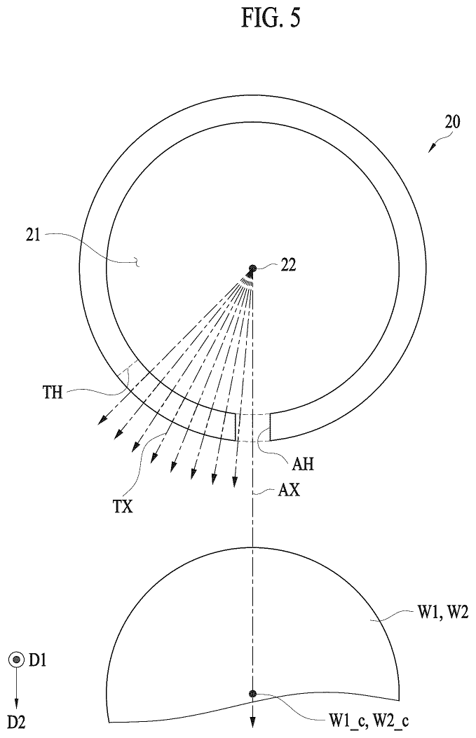

According to one or more embodiments, the plurality of wafers W may be stacked along a first direction D1 within the process chamber 30. The first direction D1 in this specification may refer to a direction in which the process chamber 30 is extended and a direction crossing and/or perpendicular to a main surface of the wafers W. The first direction D1, a longitudinal direction of the gas nozzle 20, a vertical direction, and a direction in which the plurality of wafers W are stacked in this specification may be directions parallel to each other. In this specification, a second direction D2 may be a direction crossing the first direction D1 and in which a central axis AX (see FIG. 5) of an alignment hole AH of the gas nozzle 20 described later may be extended.

According to one or more embodiments, the plurality of wafers W may be wafers composing batch 1 in an ALD process of the batch 1. According to one or more embodiments, among the plurality of wafers W stacked along the first direction D1, dummy wafers may be disposed at a bottommost portion and a topmost portion. However, embodiments are not limited thereto, and according to one or more other embodiments, all wafers composing the batch 1 may be a target of a process.

According to one or more embodiments, the wafer processing apparatus 1 may include a boat 100 disposed on a topmost wafer among the plurality of wafers W within the process chamber 30. In a process with regard to the batch 1, the plurality of wafers W may be arranged at a regular interval in a vertical direction in a centered position with each other from a horizontal view. The boat 100 may be manufactured from a heat-resistant material, for example, quartz or silicon monoxide (SiO).

According to one or more embodiments, a rotating mechanism 127 facing a process room inside of the process chamber 30 and configured to rotate the boat 100 may be installed below the seal cap 126. A rotation axis 125 of the rotating mechanism 127 may rotate the wafers W by penetrating the seal cap 126, being connected to the boat 100, and rotating the boat 100. The rotating mechanism 127 may carry the boat 100 in or out of the process chamber 30 by going up and down.

According to one or more embodiments, the wafer processing apparatus 1 may include a heater 70 disposed adjacent to and/or around an outer perimeter of the process chamber 30 and configured to control a temperature inside the process chamber 30. The heater 70 may be installed in a cylinder shape around the process chamber 30 and configured to excite fuel gas within the process chamber 30.

According to one or more embodiments, the wafer processing apparatus 1 may include a temperature sensor 150 to detect a temperature within the process chamber 30. The temperature sensor 150 may be installed within the process chamber 30. Based on information on the temperature within the process chamber 30 detected by the temperature sensor 150, a conducting state of the heater 70 may be adjusted. Accordingly, the temperature sensor 150 may allow a temperature of a reaction chamber within the process chamber 30 to be in a temperature distribution targeted by a user.

According to one or more embodiments, multiple gas nozzles 20 may be installed within the process chamber 30, and each gas nozzle 20 may be connected to the gas supply pipes 40 and 60. Four gas nozzles 20 are illustrated as an example, but the number of gas nozzles is not particularly limited. Between inlet portions 146 and 166 of the gas supply pipes 40 and 60 and the process chamber 30, mass flow controllers (MFCs) 144 and 164 and on-off valves 142 and 162, which are flow controllers, may be installed.

According to one or more embodiments, the gas supply pipes 40 and 60 may be connected to the gas nozzle 20 and provide raw material gas for deposition on the wafers W, for example, halosilane raw material gas including silicon (Si) and halogen elements. As the halosilane raw material gas, a carbon (C)-free raw material gas containing silicon (Si) and chlorine (Cl), in other words, inorganic chlorosilane raw material gas may be used. As inorganic chlorosilane raw material gas, hexachlorodisilane (Si₂Cl₆, abbreviated as HCDS) gas, octachlorotrisilane (Si₃Cl₈) gas, or dichlorosilane (SiH₂Cl₂, abbreviated as DCS) gas may be used. In addition, diisopropylaminosilane (DIPAS) gas may be used as the raw material gas. These gases may be operated as a silicon (Si) source in wafer film deposition. However, a type of the raw material gas is not limited to the aforementioned gases.

According to one or more embodiments, hydrocarbon gas as a carbon (C)-containing gas operating as a carbon (C) source for the thin film deposition may be supplied through the gas supply pipes 40 and 60. As hydrocarbon gas, for example, propylene (C₃H₆) gas may be used. In addition, oxygen (O)-containing gas and hydrogen (H)-containing gas, which operate as a reaction gas may be supplied to the reaction chamber through the gas supply pipes 40 and 60. For example, oxygen (O₂) gas may be used as oxygen (O)-containing gas and ammonia (NH₃) gas may be used as hydrogen (H)-containing gas. In addition, gas such as inert gas may be supplied for a deposition process through the gas supply pipes 40 and 60. Such raw material gas, reaction gas, and inert gas may be collectively referred to as raw material processing gas.

According to one or more embodiments, charging tanks 148 and 168 may be disposed adjacent to and/or around the inlet portions 146 and 166 of the gas supply pipes 40 and 60. The charging tanks 148 and 168 may be connected to the gas supply pipes 40 and 60. The charging tanks 148 and 168 may include a source gas, a reaction gas, a first purge gas, or a second purge gas.

According to one or more embodiments, within the process chamber 30, an exhaust pipe 80 exhausting a gas of the reaction chamber may be installed. In the exhaust pipe 80, a pressure sensor 185 sensing pressure within the reaction chamber and an auto pressure valve 184 may be provided. In addition, a vacuum pump 182 may be connected to the exhaust pipe 80 to allow an exhaust system of the wafer processing apparatus 1 to be embodied.

According to one or more embodiments, the gas nozzle 20 may be installed in a longitudinal direction along a direction from the bottom toward the top of an interior wall of the process chamber 30 in a ring-shaped space between the interior wall of the process chamber 30 and the plurality of wafers W. The gas nozzle 20 may be installed perpendicularly to a surface of the wafers W at a side of an outer peripheral surface of the wafers W carried within the process chamber 30. In the gas nozzle 20, a hole (for example, the alignment hole AH) supplying gas toward a center of the wafers W by being supplied with raw material gas may be formed. A major flow of gas of the alignment hole AH may proceed to a horizontal direction parallel to the surface of the wafers W.

According to one or more embodiments, a hole may be positioned per a sheet of the wafers W in the gas nozzle 20 and a gas sprayed from the hole may be deposited on the wafers W. In a deposition operation, the amount of a gas sprayed from each hole may be a factor determining a deposition thickness of the wafers W.

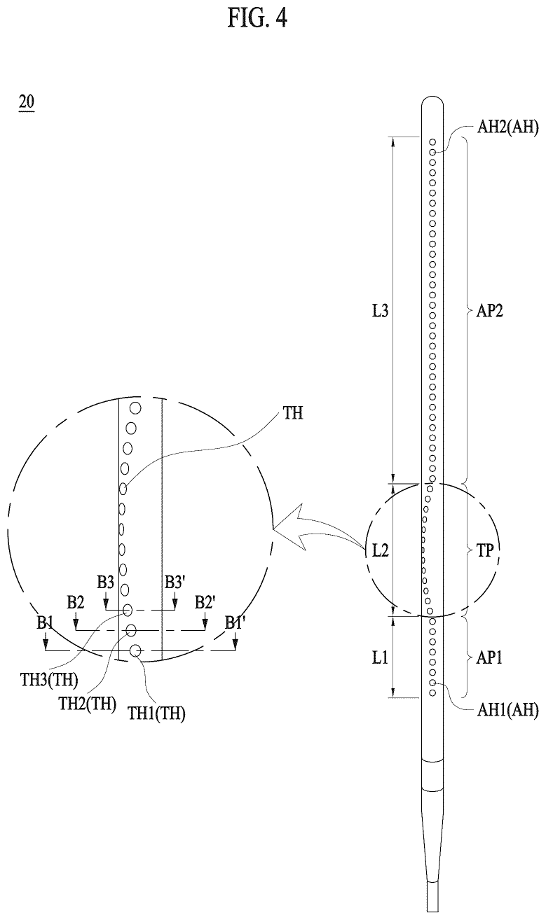

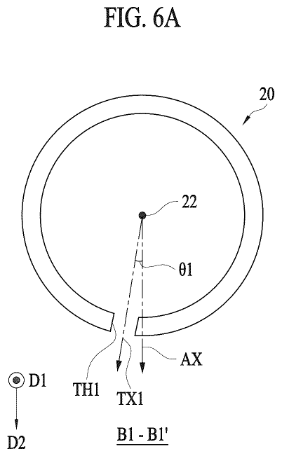

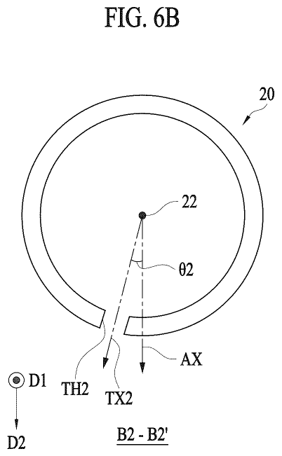

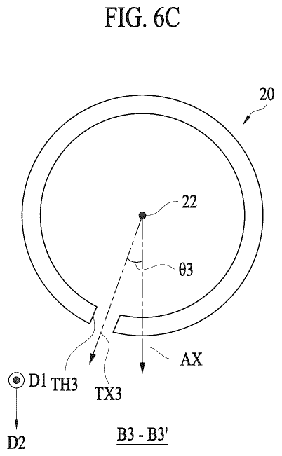

FIG. 4 is a schematic diagram illustrating the gas nozzle 20 according to one or more embodiments, and FIG. 5 is a schematic view for explaining an alignment relation between the gas nozzle 20 illustrated in FIG. 4 and a wafer, and FIG. 6A is an exemplary diagram illustrating a cross section taken along B1-B1′ line in FIG. 4, and FIG. 6B is an exemplary diagram illustrating a cross section taken along B2-B2′ line in FIG. 4, and FIG. 6C is an exemplary diagram illustrating a cross section taken along B3-B3′ line in FIG. 4.

According to one or more embodiments, the gas nozzle 20 may be extended lengthwise along a longitudinal direction (the first direction D1). The gas nozzle 20 may include a first alignment part AP1, a second alignment part AP2, and a tilting part TP including a hole disposed at a position facing each of the plurality of wafers W along the longitudinal direction.

As shown in FIG. 4, the first alignment part AP1 may be positioned at a bottom portion of the gas nozzle 20, and the second alignment part AP2 may be positioned at a top portion of the gas nozzle 20. The tilting part TP may be positioned between the first alignment part AP1 and the second alignment part AP2 along the longitudinal direction of the gas nozzle 20. Although in FIG. 4, the tilting part TP is illustrated to be positioned below a center of the gas nozzle 20 in the first direction D1, embodiments are not limited thereto, and the tilting part TP may be positioned above the center of the gas nozzle 20, and the tilting part TP may be positioned at the center of the gas nozzle 20.

According to one or more embodiments, the first alignment part AP1 may have a first length L1 along the first direction D1, and the tilting part TP may have a second length L2 along the first direction D1, and the second alignment part AP2 may have a third length L3 along the first direction D1. In FIG. 4, the third length L3 of the second alignment part AP2 is longer than the first length L1 and the second length L2. However, embodiments are not limited thereto, and a magnitude relation of the first length L1 of the first alignment part AP1, the second length L2 of the tilting part TP, and the third length L3 of the second alignment part AP2 may be different from what illustrated in FIG. 4. Lengths of the first alignment part AP1, the second alignment part AP2, and the tilting part TP along the first direction D1 may be in proportion to the number of holes formed in each area.

According to one or more embodiments, each of the first alignment part AP1 and the second alignment part AP2 may include the alignment hole AH aligned to face the center of the wafers W, and the tilting part TP may include a tilting hole TH obliquely aligned with the center of the wafers W. In FIG. 5, a top plan view looking down the gas nozzle 20 in the opposite direction of the first direction D1 is illustrated. Within the gas nozzle 20, a fluid space 21 may be formed. In FIG. 5, the alignment hole AH of the gas nozzle 20 is illustrated as a solid line and a plurality of the tilting holes TH as a dotted line. The first alignment part AP1 may include at least one or more first alignment holes AH1, and the second alignment part AP2 may include at least one or more second alignment holes AH2, and the tilting part TP may include at least one or more tilting holes TH.

According to one or more embodiments, all of a plurality of the alignment holes AH and the plurality of the tilting holes TH may have diameters may be equal to each other. Accordingly, an amount of a gas sprayed from each of the plurality of the alignment holes AH and the plurality of the tilting holes TH may be uniform within a margin of error. Furthermore, distances where the plurality of the alignment holes AH and the plurality of the tilting holes TH are spaced apart from each other along the first direction D1 may be equal to each other throughout the gas nozzle 20. Each of the plurality of wafers W may be stacked at an equal interval in the batch 1, and each of the plurality of the alignment holes AH and each of the plurality of the tilting holes TH positioned corresponding to the plurality of wafers W may be disposed at an equal interval.

According to one or more embodiments, the plurality of wafers W may be arranged in the first direction D1 to individually correspond to positions of the holes (for example, the alignment hole AH and the tilting hole TH) on the gas nozzle 20 within the process chamber 30. For example, each hole formed on the gas nozzle 20 may be positioned to face the wafers W. In this specification, a wafer positioned to face the alignment hole AH among the plurality of wafers W may be defined as a first wafer W1, and a wafer positioned to face the tilting hole TH among the plurality of wafers W may be defined as a second wafer W2.

According to one or more embodiments, the central axis AX of the alignment hole AH may pass through a central axis W1_c of the first wafer W1 from a plan view that crosses the first direction D1. The central axis AX of the alignment hole AH may also pass through a central axis 22 of the gas nozzle 20. The central axis 22 of the gas nozzle 20 and the central axis W1_c of the first wafer W1 may extend along a direction parallel to the first direction D1 (the longitudinal direction of the gas nozzle 20), and the central axis AX of the alignment hole AH may extend along the second direction D2. The alignment hole AH may be a hole completely aligned to face the first wafer W1.

According to one or more embodiments, a central axis TX of the tilting hole TH may be misaligned with a central axis W2_c of the second wafer W2 from a plan view that crosses the first direction D1. For example, the central axis TX of the tilting hole TH may not pass through the central axis W2_c of the second wafer W2. For example, the central axis TX of the tilting hole TH may be spaced apart from the central axis W2_c of the second wafer W2. The central axis TX of the tilting hole TH may pass through the central axis 22 of the gas nozzle 20. The tilting hole TH may be a hole formed along a circumferential direction in the gas nozzle 20 having a ring-shaped cross section. The central axis W2_c of the second wafer W2 may be an axis corresponding to the central axis W1_c of the first wafer W1. The tilting hole TH may be a hole obliquely aligned with a center of the second wafer W2.

According to one or more embodiments, the tilting part TP may include the plurality of the tilting holes TH consecutively disposed along the first direction D1 and having different tilting angles from each other. According to one or more embodiments, the tilting part TP may include four or more tilting holes TH having different tilting angles from each other, but embodiments are not limited thereto, and the tilting part TP may include three tilting holes TH having different tilting angles from each other as illustrated in FIGS. 6A to 6C.

Hereinafter, detailed description is provided with reference to FIGS. 6A to 6C. According to one or more embodiments, the tilting part TP may include a first tilting hole TH1, a second tilting hole TH2, and a third tilting hole TH3. The first tilting hole TH1 may have a first central axis TX1 misaligned by a first angle θ1 from the central axis AX of the alignment hole AH. The second tilting hole TH2 may have a second central axis TX2 misaligned by a second angle θ2 from the central axis AX of the alignment hole AH. The third tilting hole TH3 may have a third central axis TX3 misaligned by a third angle θ3 from the central axis AX of the alignment hole AH. The first tilting hole TH1 may be a hole positioned lower than the second tilting hole TH2 in the first direction D1, and the second tilting hole TH2 may be a hole positioned lower than the third tilting hole TH3 in the first direction D1. The second angle θ2 may be greater than the first angle θ1, and the third angle θ3 may be greater than the second angle θ2. For example, the second tilting hole TH2 may be more obliquely aligned with the center of the second wafer W2 than the first tilting hole TH1, and the third tilting hole TH3 may be more obliquely aligned with the center of the second wafer W2 than the second tilting hole TH2.

According to one or more embodiments, a difference between the first angle θ1 and the second angle θ2 may be equal to a difference between the second angle θ2 and the third angle θ3. For example, tilted angles of the central axes TX1, TX2, and TX3 of the first, second, and third tilting holes TH1, TH2, and TH3, which are sequentially formed along the first direction D1, from the central axis AX of the alignment hole AH may linearly increase or decrease.

According to one or more embodiments, as the reaction gas sprayed from the gas nozzle 20 is fluid, a flow rate of an exposed gas may be different depending on a level of the wafers W stacked in the first direction D1 within the process chamber 30. When every hole on the gas nozzle 20 is completely aligned to face the wafers W, a flow rate of a gas sprayed at a specific vertical level may be relatively high. Here, the tilting part TP may be formed in an area of the gas nozzle 20 corresponding to the vertical level. More elaborate control for the flow rate of a gas may be possible as the plurality of the tilting holes TH have different tilting angles from each other within the tilting part TP.

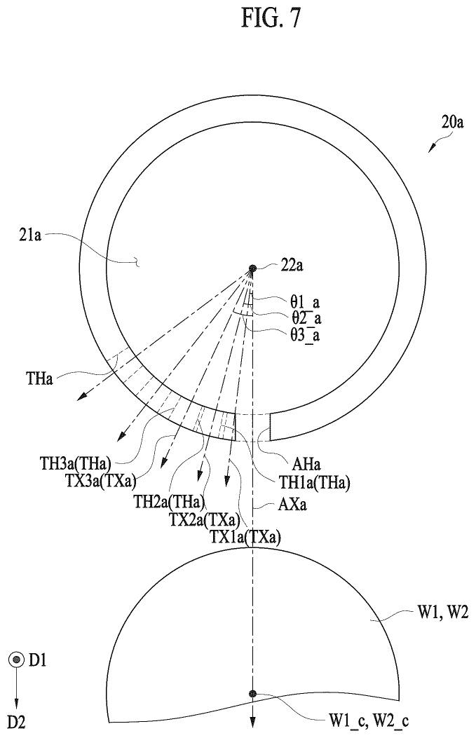

FIG. 7 is a schematic view for explaining an alignment relation between a gas nozzle 20a and a wafer according to one or more other embodiments.

The gas nozzle 20a illustrated in FIG. 7 may be almost identical or similar to the gas nozzle 20 illustrated in FIGS. 4 to 6C, except that angles of central axes TXa of a plurality of tilting holes THa tilted from a central axis AXa of an alignment hole AHa may nonlinearly increase or decrease. Accordingly, a difference from the gas nozzle 20 illustrated in FIGS. 4 to 6C is mainly described.

In FIG. 7, a top plan view looking down the gas nozzle 20a from the opposite direction of the first direction D1 is illustrated. Within the gas nozzle 20a, a fluid space 21a may be formed. In FIG. 7, the alignment hole AHa of the gas nozzle 20a is illustrated as a solid line, and the plurality of tilting holes THa as a dotted line.

According to one or more embodiments, from a plan view that crosses the first direction D1, the central axis AXa of the alignment hole AHa may pass through the central axis W1_c of the first wafer W1. The alignment hole AHa may be a hole completely aligned to face the first wafer W1. As the alignment hole AHa illustrated in FIG. 7 is practically identical to the alignment hole AH illustrated in FIGS. 4 to 6C, detailed description is omitted.

According to one or more embodiments, the plurality of tilting holes THa may be consecutively disposed along the first direction D1 and have different tilting angles from each other. According to one or more embodiments, the gas nozzle 20a may include four or more tilting holes having different tilting angles from each other, but embodiments are not limited thereto, and the gas nozzle 20a may include three tilting holes TH1a, TH2a, and TH3a having different tilting angles from each other as illustrated in FIG. 7.

A first tilting hole TH1a may have a first central axis TX1a misaligned by a first angle θ1_a from the central axis AXa of the alignment hole AHa. A second tilting hole TH2a may have a second central axis TX2a misaligned by a second angle θ2_a from the central axis AXa of the alignment hole AHa. A third tilting hole TH3a may have a third central axis TX3a misaligned by a third angle θ3_a from the central axis AXa of the alignment hole AHa. The first tilting hole TH1a may be a hole positioned lower than the second tilting hole TH2a in the first direction D1, and the second tilting hole TH2a may be a hole positioned lower than the third tilting hole TH3a in the first direction D1. The second angle θ2_a may be greater than the first angle θ1_a, and the third angle θ3_a may be greater than the second angle θ2_a. For example, the second tilting hole TH2a may be more obliquely aligned with the center of the second wafer W2 than the first tilting hole TH1a, and the third tilting hole TH3a may be more obliquely aligned with the center of the second wafer W2 than the second tilting hole TH2a.

According to one or more embodiments, a difference between the second angle θ2_a and the third angle θ3_a may be greater than a difference between the first angle θ1_a and the second angle θ2_a. For example, angles of the central axes TX1a, TX2a, and TX3a of the first, second, and third tilting holes TH1a, TH2a, and TH3a, which are sequentially formed along the first direction D1, tilted from the central axis AXa of the alignment hole AHa may nonlinearly increase or decrease. According to one or more embodiments, a difference of the tilted angles between the central axes TX1a, TX2a, and TX3a of the first, second, and third tilting holes TH1a, TH2a, and TH3a sequentially formed along the first direction D1 may increase or decrease in a manner of an nth order polynomial function or increase or decrease in a manner of an exponential function.

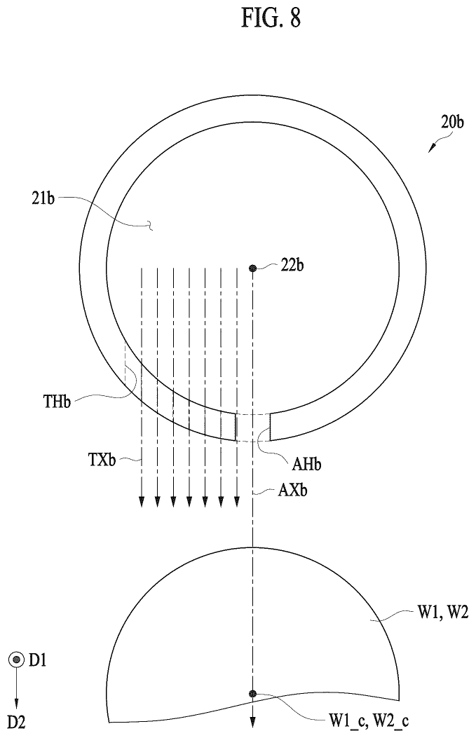

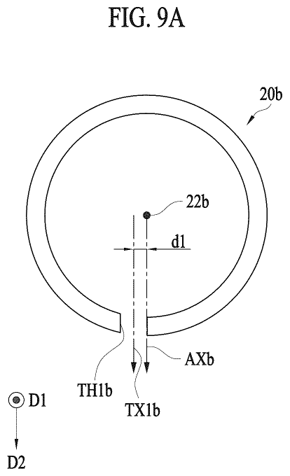

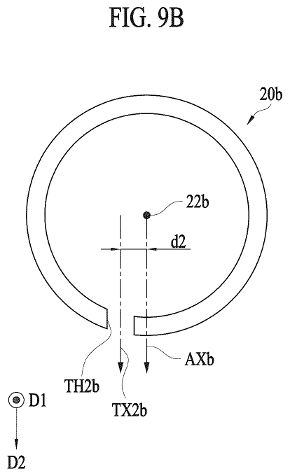

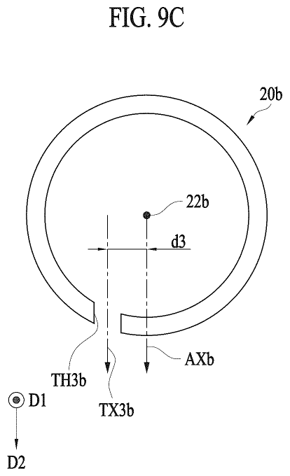

FIG. 8 is a schematic view for explaining an alignment relation between a gas nozzle 20b and a wafer according to one or more other embodiments, and FIG. 9A is an exemplary diagram illustrating a cross section of the gas nozzle illustrated in FIG. 8 and a portion corresponding to a cross section of FIG. 6A, and FIG. 9B is an exemplary diagram illustrating a cross section of the gas nozzle illustrated in FIG. 8 and a portion corresponding to a cross section of FIG. 6B, and FIG. 9C is an exemplary diagram illustrating a cross section of the gas nozzle illustrated in FIG. 8 and a portion corresponding to a cross section of FIG. 6C.

The gas nozzle 20b illustrated in FIGS. 8 to 9C may be almost identical or similar to the gas nozzle 20 illustrated in FIGS. 4 to 6C, except that a central axis TXb of a plurality of tilting holes THb are spaced apart in a horizontal direction and parallel to each other. Accordingly, a difference from the gas nozzle 20 illustrated in FIGS. 4 to 6C is mainly described.

For clearer understanding of the present disclosure, FIGS. 4 to 6C are referred to together for description. FIG. 9A may be a cross-sectional view illustrating a first tilting hole TH1b corresponding to the B1-B1′ cross-sectional view of FIG. 6A, and FIG. 9B may be a cross-sectional view illustrating a second tilting hole TH2b corresponding to the B2-B2′ cross-sectional view of FIG. 6B. In addition, FIG. 9C may be a cross-sectional view illustrating a third tilting hole TH3b corresponding to the B3-B3′ cross-sectional view of FIG. 6C.

In FIG. 8, a top plan view looking down the gas nozzle 20b from the opposite direction of the first direction D1 is illustrated. Within the gas nozzle 20b, a fluid space 21b may be formed. In FIG. 8, an alignment hole AHb of the gas nozzle 20b is illustrated as a solid line and the plurality of tilting holes THb as a dotted line.

According to one or more embodiments, from a plan view that crosses the first direction D1, a central axis AXb of the alignment hole AHb may pass through the central axis W1_c of the first wafer W1. The alignment hole AHb may be a hole completely aligned to face the first wafer W1. As the alignment hole AHb illustrated in FIGS. 8 to 9C is practically identical to the alignment hole AH illustrated in FIGS. 4 to 6C, detailed description is omitted.

According to one or more embodiments, the gas nozzle 20b may include the plurality of tilting holes THb consecutively disposed along the first direction D1 and having different tilting angles from each other. According to example embodiments, the gas nozzle 20b may include four or more tilting holes having different tilting angles from each other, but embodiments are not limited thereto, and the gas nozzle 20b may include three tilting holes THb having different tilting angles from each other as illustrated in FIGS. 9A to 9C to be described for clearer understanding.

According to one or more embodiments, the gas nozzle 20b may include the first, second, and third tilting holes TH1b, TH2b, and TH3b. Central axes TX1b, TX2b, and TX3b of the tilting holes TH1b, TH2b, and TH3b illustrated in FIGS. 9A to 9C may not pass through a central axis 22b of the gas nozzle 20b from a plan view, unlike the tilting holes TH1, TH2, and TH3 illustrated in FIGS. 6A to 6C. For example, the central axes TX1b, TX2b, and TX3b of the tilting holes TH1b, TH2b, and TH3b may be spaced apart from the central axis 22b of the gas nozzle 20b from a plan view. The central axes TX1b, TX2b, and TX3b of a plurality of the tilting holes TH1b, TH2b, and TH3b may be parallel to the central axis AXb of the alignment hole AHb and spaced apart in a horizontal direction that crosses the first direction D1 and the second direction D2. Accordingly, a gas sprayed through the plurality of the tilting holes TH1b, TH2b, and TH3b may be sprayed in a direction parallel to a gas sprayed through the alignment hole AHb.

According to one or more embodiments, the first tilting hole TH1b may have a first central axis TX1b spaced apart by a first distance d1 from the central axis AXb of the alignment hole AHb. The second tilting hole TH2b may have a second central axis TX2b spaced apart by a second distance d2 from the central axis AXb of the alignment hole AHb. The third tilting hole TH3b may have a third central axis TX3b spaced apart by a third distance d3 from the central axis AXb of the alignment hole AHb. The first tilting hole TH1b may be a hole positioned lower than the second tilting hole TH2b in the first direction D1, and the second tilting hole TH2b may be a hole positioned lower than the third tilting hole TH3b in the first direction D1. The second distance d2 may be greater than the first distance d1, and the third distance d3 may be greater than the second distance d2. For example, the second tilting hole TH2b may be more obliquely aligned with the center of the second wafer W2 than the first tilting hole TH1b, and the third tilting hole TH3b may be more obliquely aligned with the center of the second wafer W2 than the second tilting hole TH2b. However, a gas sprayed through the plurality of the tilting holes TH1b, TH2b, and TH3b illustrated in FIGS. 9A to 9C may be sprayed in a direction parallel to a direction where a gas is sprayed through the alignment hole AHb, unlike a gas sprayed through a plurality of the tilting holes TH1, TH2, and TH3 illustrated in FIGS. 6A to 6C.

According to one or more embodiments, a difference between the first distance d1 and the second distance d2 may be equal to a difference between the second distance d2 and the third distance d3. For example, distances where the central axes TX1b, TX2b, and TX3b of the plurality of the tilting holes TH1b, TH2b, and TH3b sequentially formed along the first direction D1 are spaced apart from the central axis AXb of the alignment hole AHb may linearly increase or decrease.

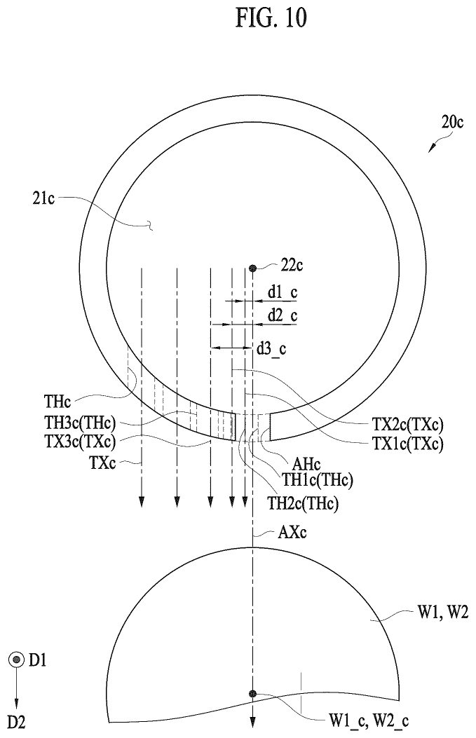

FIG. 10 is a schematic view for explaining an alignment relation between a gas nozzle 20c and a wafer according to one or more other embodiments.

The gas nozzle 20c illustrated in FIG. 10 and the gas nozzle 20b illustrated in FIGS. 8 to 9C may be almost identical or similar to each other, except that distances where central axes TXc of a plurality of tilting holes THc are spaced apart from a central axis AXc of an alignment hole AHc may nonlinearly increase or decrease. Accordingly, a difference from the gas nozzle 20b illustrated in FIGS. 8 to 9C is mainly described.

In FIG. 10, a top plan view looking down the gas nozzle 20c from the opposite direction of the first direction D1 is illustrated. Within the gas nozzle 20c, a fluid space 21c may be formed. In FIG. 10, the alignment hole AHc of the gas nozzle 20c is illustrated as a solid line and the plurality of tilting holes THc as a dotted line.

According to one or more embodiments, the central axis AXc of the alignment hole AHc may pass through the central axis W1_c of the first wafer W1 from a plan view that crosses the first direction D1. The alignment hole AHc may be a hole completely aligned to face the first wafer W1. As the alignment hole AHc illustrated in FIG. 10 is practically identical to the alignment hole AH illustrated in FIGS. 4 to 6C, detailed description is omitted.

According to one or more embodiments, the gas nozzle 20c may include the plurality of tilting holes THc consecutively disposed along the first direction D1 and having different separation distances from the alignment hole AHc. According to one or more embodiments, the gas nozzle 20c may include four or more tilting holes having different separation distances from the alignment hole AHc, but embodiments are not limited thereto, and the gas nozzle 20c may include three tilting holes THc having the different separation distances as illustrated in FIG. 10 to be described for clearer understanding.

According to one or more embodiments, the gas nozzle 20c may include a first tilting hole TH1c, a second tilting hole TH2c, and a third tilting hole TH3c. The first tilting hole TH1c may have a first central axis TX1c spaced apart by a first distance d1_c from the central axis AXc of the alignment hole AHc. The second tilting hole TH2c may have a second central axis TX2c spaced apart by a second distance d2_c from the central axis AXc of the alignment hole AHc. The third tilting hole TH3c may have a third central axis TX3c spaced apart by a third distance d3_c from the central axis AXc of the alignment hole AHc. The first tilting hole TH1c may be a hole positioned lower than the second tilting hole TH2c in the first direction D1, and the second tilting hole TH2c may be a hole positioned lower than the third tilting hole TH3c in the first direction D1. The second distance d2_c may be greater than the first distance d1_c, and the third distance d3_c may be greater than the second distance d2_c. For example, the second tilting hole TH2c may be more obliquely aligned with the center of the second wafer W2 than the first tilting hole TH1c, and the third tilting hole TH3c may be more obliquely aligned with the center of the second wafer W2 than the second tilting hole TH2c.

According to one or more embodiments, a difference between the second distance d2_c and the third distance d3_c may be greater than a difference between the first distance d1_c and the second distance d2_c. For example, distances where the central axes TX1c, TX2c, and TX3c of a plurality of the tilting holes TH1c, TH2c, and TH3c sequentially formed along the first direction D1 are spaced apart from the central axis AXc of the alignment hole AHc may nonlinearly increase or decrease. According to one or more embodiments, a separation distance difference between the central axes TX1c, TX2c, and TX3c of the plurality of the tilting holes TH1c, TH2c, and TH3c sequentially formed along the first direction D1 may increase or decrease in a manner of an nth order polynomial function or increase or decrease in a manner of an exponential function.

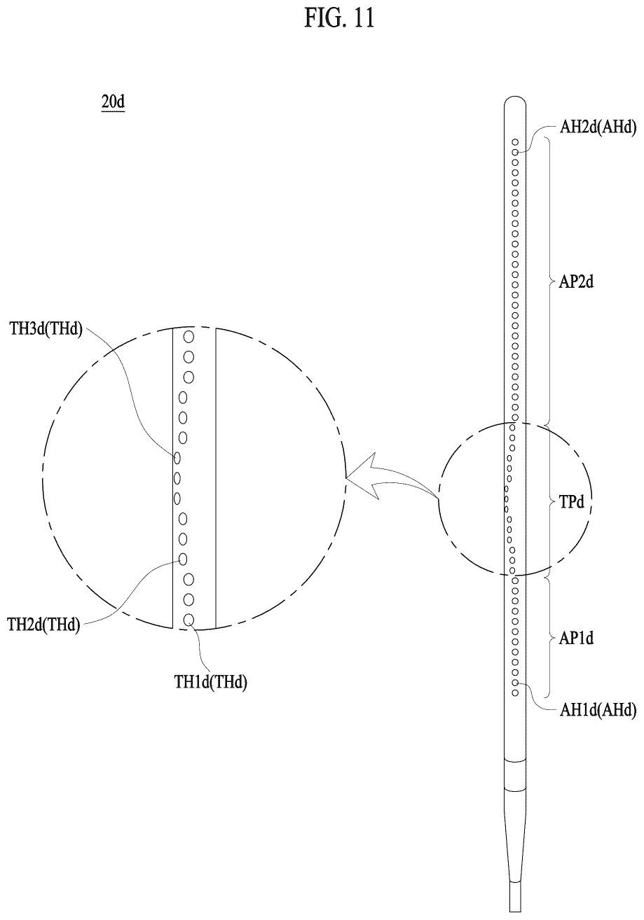

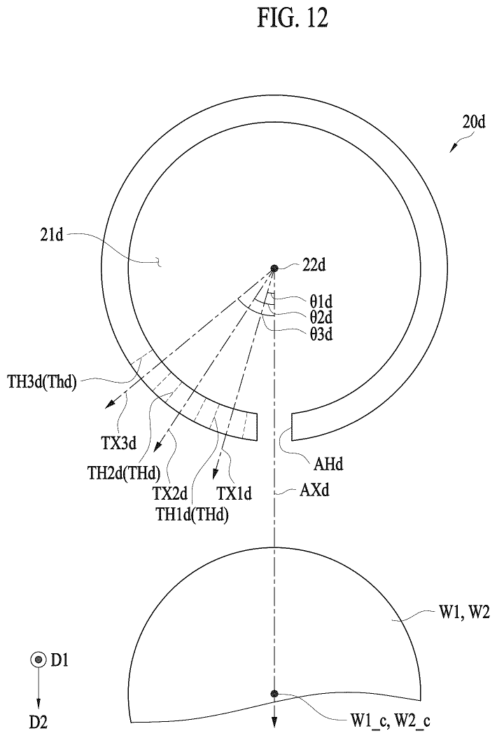

FIG. 11 is a schematic diagram illustrating a gas nozzle 20d according to one or more other embodiments, and FIG. 12 is a schematic view for explaining an alignment relation between the gas nozzle 20d illustrated in FIG. 11 and a wafer.

The gas nozzle 20d illustrated in FIGS. 11 and 12 may be almost identical or similar to the gas nozzle 20 illustrated in FIGS. 4 to 6C, except that tilting holes THd having a same central axis are consecutively disposed along the first direction D1. Accordingly, a difference from the gas nozzle 20 illustrated in FIGS. 4 to 6C is mainly described.

According to one or more embodiments, the gas nozzle 20d may be extended lengthwise along a longitudinal direction (the first direction D1). The gas nozzle 20d may include a first alignment part AP1d, a second alignment part AP2d, and a tilting part TPd including a hole disposed at a position facing each of the plurality of wafers W along the longitudinal direction. A description about a positional relation and lengths of the first alignment part AP1d, the second alignment part AP2d, and the tilting part TPd illustrated in FIG. 11 overlaps with the description explained with reference to FIG. 4, and thus, is omitted hereinafter.

In FIG. 12, a top plan view looking down the gas nozzle 20d from the opposite direction of the first direction D1 is illustrated. Within the gas nozzle 20d, a fluid space 21d may be formed. In FIG. 12, an alignment hole AHd of the gas nozzle 20d is illustrated as a solid line and a plurality of the tilting holes THd as a dotted line.

According to one or more embodiments, the first alignment part AP1d may include at least one of a first alignment hole AH1d, and the second alignment part AP2d may include at least one or more of a second alignment hole AH2d, and the tilting part TPd may include at least one or more of a tilting hole THd. The tilting part TPd may include a first tilting holes TH1d, second tilting holes TH2d, and third tilting holes TH3d. A central axis TX1d of the plurality of the first tilting holes TH1d may be misaligned by a first angle θ1d from a central axis AXd of the alignment hole AHd. The plurality of the first tilting holes TH1d may be consecutively disposed along the first direction D1. As an example, three of the first tilting holes TH1d may be consecutively disposed along the first direction D1. Here, the three of the first tilting holes TH1d may be positioned at a bottommost end of the tilting part TPd. In addition, another three of the first tilting holes TH1d may be consecutively disposed along the first direction D1 at a topmost end of the tilting part TPd.

According to one or more embodiments, a central axis TX2d of the second tilting holes TH2d may be misaligned by a second angle θ2d from the central axis AXd of the alignment hole AHd. The second tilting holes TH2d may be consecutively disposed along the first direction D1. As an example, three of the second tilting holes TH2d may be consecutively disposed along the first direction D1. Here, the three of the second tilting holes TH2d may be consecutively disposed at a lower portion of the tilting part TPd between the first tilting holes TH1d and the third tilting holes TH3d along the first direction D1. In addition, another three of the second tilting holes TH2d may be consecutively disposed at an upper portion of the tilting part TPd between the first tilting holes TH1d and the third tilting holes TH3d along the first direction D1.

According to one or more embodiments, a central axis TX3d of the plurality of the third tilting holes TH3d may be misaligned by a third angle θ3d from the central axis AXd of the alignment hole AHd. The third tilting holes TH3d may be consecutively disposed along the first direction D1. As an example, three of the third tilting holes TH3d may be consecutively disposed along the first direction D1. Here, the three of the third tilting holes TH3d may be positioned between the three of the second tilting holes TH2d positioned at a lower portion of the gas nozzle 20d and the three of the second tilting holes TH2d positioned at an upper portion of the gas nozzle 20d. In this specification, the first, second, and third tilting holes TH1d, TH2d, and TH3d are illustrated as being consecutively disposed in groups of three, but embodiments are not limited thereto, and the number of the first, second, and third tilting holes TH1d, TH2d, and TH3d disposed consecutively may vary depending on example embodiments.

According to one or more embodiments, the second angle θ2d may be greater than the first angle θ1d, and the third angle θ3d may be greater than the second angle θ2d. A difference between the first angle θ1d and the second angle θ2d may be equal to a difference between the second angle θ2d and the third angle θ3d. For example, angles where the central axes TX1d, TX2d, and TX3d of the plurality of the tilting holes TH1d, TH2d, and TH3d sequentially formed along the first direction D1 are tilted from the central axis AXd of the alignment hole AHd may linearly increase or decrease.

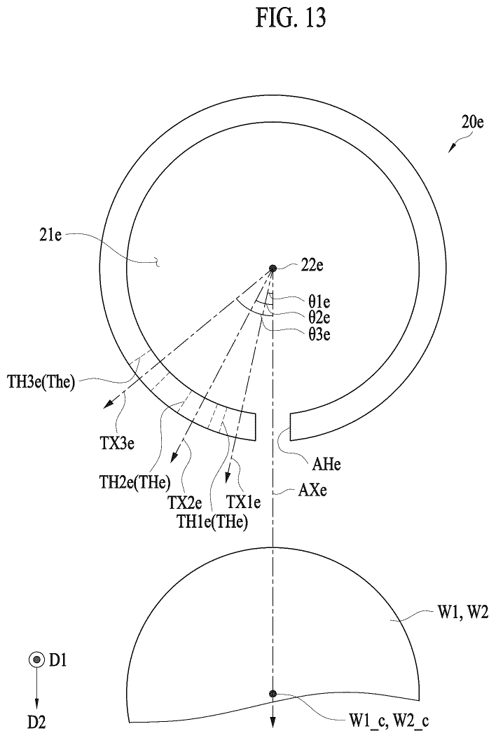

FIG. 13 is a schematic view for explaining an alignment relation between a gas nozzle 20e and a wafer according to one or more other embodiments.

The gas nozzle 20e illustrated in FIG. 13 may be almost identical or similar to the gas nozzle 20d illustrated in FIGS. 11 and 12, except that angles where central axes TX1e, TX2e, and TX3e of tilting holes TH1e, TH2e, and TH3e are tilted from a central axis AXe of an alignment hole AHe may nonlinearly increase or decrease. Accordingly, a difference from the gas nozzle 20d illustrated in FIGS. 11 and 12 is mainly described.

According to one or more embodiments, the gas nozzle 20e may include first tilting holes TH1e, second tilting holes TH2e, and third tilting holes TH3e. The first tilting holes TH1e may have a first central axis TX1e misaligned by a first angle θ1e from the central axis AXe of the alignment hole AHe. The second tilting holes TH2e may have a second central axis TX2e misaligned by a second angle θ2e from the central axis AXe of the alignment hole AHe. The third tilting holes TH3e may have a third central axis TX3e misaligned by a third angle θ3e from the central axis AXe of the alignment hole AHe. The second angle θ2e may be greater than the first angle θ1e, and the third angle θ3e may be greater than the second angle θ2e. In other words, the second tilting holes TH2e may be more obliquely aligned with the center of the second wafer W2 than the first tilting holes TH1e, and the third tilting holes TH3e may be more obliquely aligned with the center of the second wafer W2 than the second tilting holes TH2e.

According to one or more embodiments, a difference between the second angle θ2e and the third angle θ3e may be greater than a difference between the first angle θ1e and the second angle θ2e. For example, angles where the central axes TX1e, TX2e, and TX3e of the plurality of the tilting holes TH1e, TH2e, and TH3e sequentially formed along the first direction D1 are tilted from the central axis AXe of the alignment hole AHe may be nonlinearly increase or decrease. According to one or more embodiments, a difference of the tilted angles between the central axes TX1e, TX2e, and TX3e of the plurality of the tilting holes TH1e, TH2e, and TH3e sequentially formed along the first direction D1 may increase or decrease in a manner of an nth order polynomial function or increase or decrease in a manner of an exponential function.

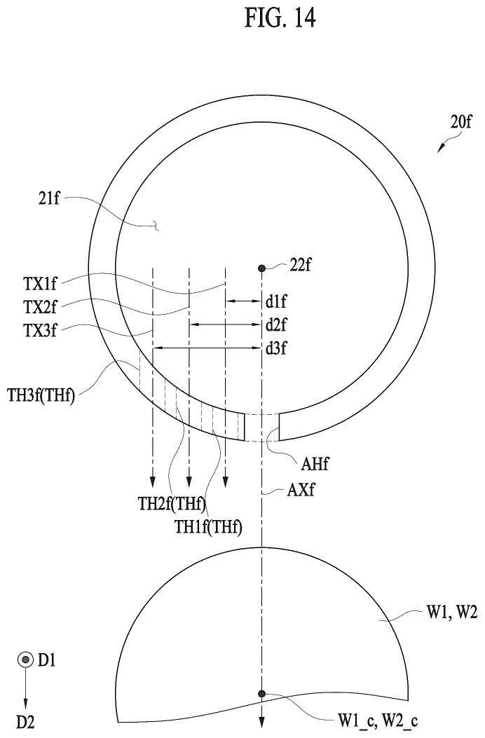

FIG. 14 is a schematic view for explaining an alignment relation between a gas nozzle 20f and a wafer according to one or more other embodiments.

The gas nozzle 20f illustrated in FIG. 14 may be almost identical or similar to the gas nozzle 20d illustrated in FIGS. 11 and 12, except that central axes TX1f, TX2f, and TX3f of a plurality of tilting holes THf are spaced apart in a horizontal direction and formed parallel to each other. Accordingly, a difference from the gas nozzle 20d illustrated in FIGS. 11 and 12 is mainly described.

According to one or more embodiments, the gas nozzle 20f may include first tilting holes TH1f, second tilting holes TH2f, and third tilting holes TH3f. The central axes TX1f, TX2f, and TX3f of the tilting holes THf illustrated in FIG. 14, unlike the central axes TX1d, TX2d, and TX3d of the tilting hole THd illustrated in FIGS. 11 and 12, may not pass through a central axis 22f of the gas nozzle 20f from a plan view. For example, the central axes TX1f, TX2f, and TX3f of the tilting holes THf may be spaced apart from the central axis 22f of the gas nozzle 20f in a plan view. The central axes TX1f, TX2f, and TX3f of the plurality of the tilting holes THf may be parallel to a central axis AXf of an alignment hole AHf and spaced apart in a horizontal direction that crosses the first direction D1 and the second direction D2. Accordingly, a gas sprayed through the plurality of the tilting holes THf may be sprayed in a direction parallel to a gas sprayed through the alignment hole AHf.

The first tilting holes TH1f may have a first central axis TX1f spaced apart by a first distance d1f from the central axis AXf of the alignment hole AHf. The second tilting holes TH2f may have a second central axis TX2f spaced apart by a second distance d2f from the central axis AXf of the alignment hole AHf. The third tilting holes TH3f may have a third central axis TX3f spaced apart by a third distance d3f from the central axis AXf of the alignment hole AHf. The second distance d2f may be greater than the first distance d1f, and the third distance d3f may be greater than the second distance d2f. In other words, the second tilting hole TH2f may be more obliquely aligned with the center of the second wafer W2 than the first tilting hole TH1f, and the third tilting hole TH3f may be more obliquely aligned with the center of the second wafer W2 than the second tilting hole TH2f. However, a gas sprayed through the tilting holes TH1f, TH2f, and TH3f illustrated in FIG. 14, unlike a gas sprayed through the plurality of the tilting holes TH1d, TH2d, and TH3d illustrated in FIGS. 11 and 12, may be sprayed in a direction parallel to a direction of the gas sprayed through the alignment hole AHf.

According to one or more embodiments, a difference between the first distance d1f and the second distance d2f may be equal to a difference between the second distance d2f and the third distance d3f. For example, distances where the central axes TX1f, TX2f, and TX3f of the tilting holes TH1f, TH2f, and TH3f sequentially formed along the first direction D1 are spaced apart from the central axis AXf of the alignment hole AHf may be linearly increase or decrease.

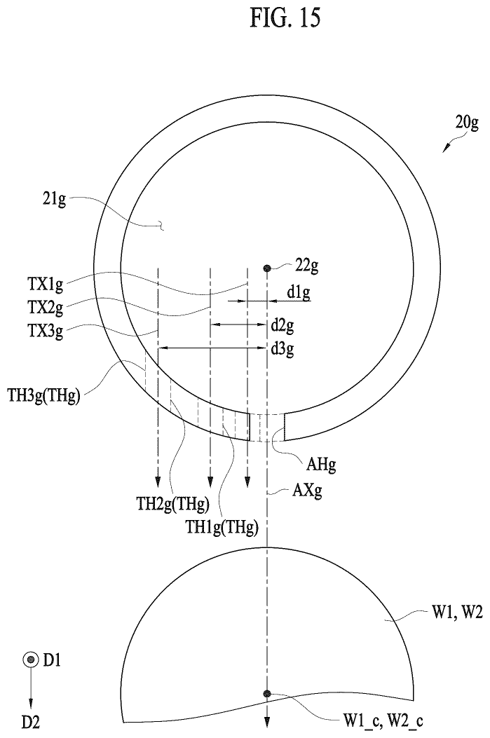

FIG. 15 is a schematic view for explaining an alignment relation between a gas nozzle 20g and a wafer according to one or more other embodiments.

The gas nozzle 20g illustrated in FIG. 15 may be almost identical or similar to the gas nozzle 20f illustrated in FIG. 14, except that distances where central axes TX1g, TX2g, and TX3g of a plurality of tilting holes THg are spaced apart from a central axis AXg of an alignment hole AHg may nonlinearly increase or decrease. Accordingly, a difference from the gas nozzle 20f illustrated in FIG. 14 is mainly described.

According to one or more embodiments, the gas nozzle 20g may include a first tilting hole TH1g, a second tilting hole TH2g, and a third tilting hole TH3g. The first tilting hole TH1g may have a first central axis TX1g spaced apart by a first distance d1g from the central axis AXg of the alignment hole AHg. The second tilting hole TH2g may have a second central axis TX2g spaced apart by a second distance d2g from the central axis AXg of the alignment hole AHg. The third tilting hole TH3g may have a third central axis TX3g spaced apart by a third distance d3g from the central axis AXg of the alignment hole AHg.

According to one or more embodiments, a difference between the second distance d2g and the third distance d3g may be greater than a difference between the first distance d1g and the second distance d2g. For example, distances where the central axes TX1g, TX2g, and TX3g of the tilting holes TH1g, TH2g, and TH3g sequentially formed along the first direction D1 are spaced apart from the central axis AXg of the alignment hole AHg may nonlinearly increase or decrease. According to example embodiments, a separation distance difference between the central axes TX1g, TX2g, and TX3g of the tilting holes TH1g, TH2g, and TH3g sequentially formed along the first direction D1 may increase or decrease in a manner of an nth order polynomial function or increase or decrease in a manner of an exponential function.

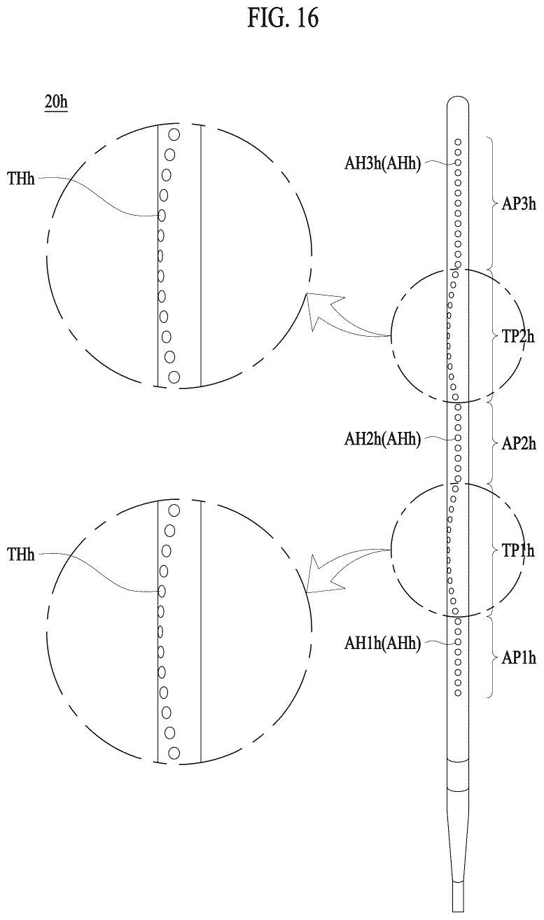

FIG. 16 is a schematic diagram illustrating a gas nozzle 20h according to one or more other embodiments.

The gas nozzle 20h illustrated in FIG. 16 may be almost identical to or similar to the gas nozzle 20 illustrated in FIGS. 4 to 6C, except that a plurality of tilting parts TP1h and TP2h are provided. Accordingly, a difference from the gas nozzle 20 illustrated in FIGS. 4 to 6C is mainly described.

According to one or more embodiments, the gas nozzle 20h may be extended lengthwise in a longitudinal direction (in other words, the first direction D1). The gas nozzle 20h may include a first alignment part AP1h, a second alignment part AP2h, a third alignment part AP3h, a first tilting part TP1h, and a second tilting part TP2h including a hole disposed at a position facing each of the plurality of wafers W along the longitudinal direction. The tilting parts TP1h and TP2h may be provided, and although the number of the tilting parts TP1h and TP2h is illustrated as two in FIG. 16, the number of the tilting parts TP1h and TP2h is not limited thereto.

As illustrated in FIG. 16, the first alignment part AP1h may be positioned at a bottommost portion of the gas nozzle 20h, and the second alignment part AP2h may be positioned in a middle of the gas nozzle 20h, and the third alignment part AP3h may be positioned at a topmost portion of the gas nozzle 20h. The first tilting part TP1h may be positioned between the first alignment part AP1h and the second alignment part AP2h along the longitudinal direction of the gas nozzle 20h. Furthermore, the second tilting part TP2h may be positioned between the second alignment part AP2h and the third alignment part AP3h along the longitudinal direction of the gas nozzle 20h.

In FIG. 16, at least two of the alignment parts AP1h, AP2h, and AP3h are illustrated as having the same length in the first direction D1, but according to one or more embodiments, the lengths of the plurality of the alignment parts AP1h, AP2h, and AP3h in the first direction D1 may be different from each other. Similarly, in FIG. 16, lengths of the plurality of the tilting parts TP1h and TP2h in the first direction D1 are illustrated as identical, but according to one or more embodiments, the lengths of the tilting parts TP1h and TP2h in the first direction D1 may be different from each other.

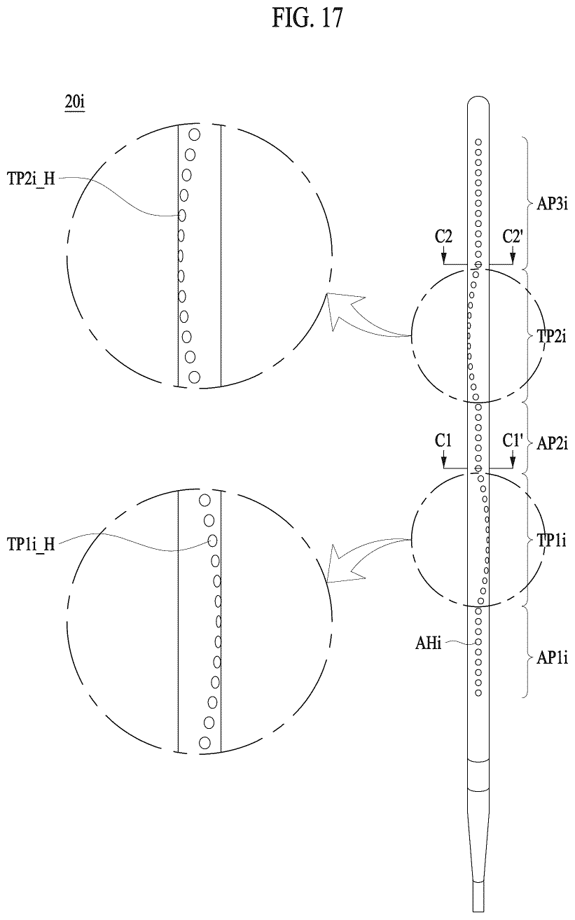

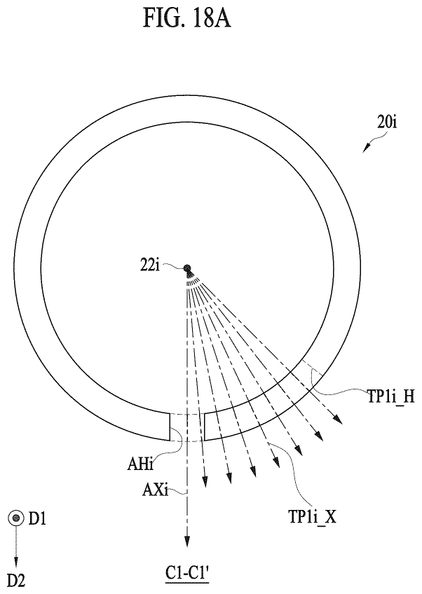

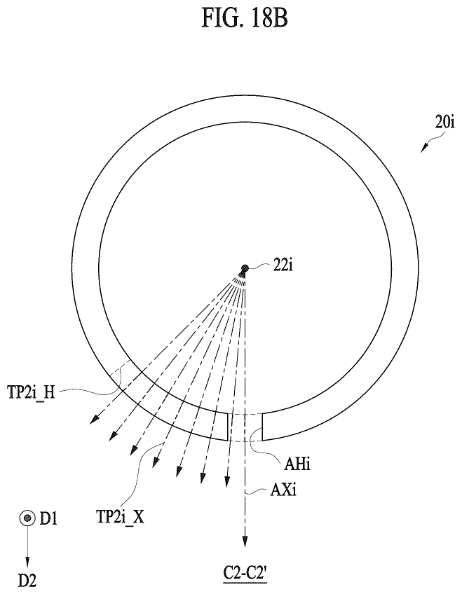

FIG. 17 is a schematic diagram illustrating a gas nozzle 20i according to one or more other embodiments, and FIG. 18A is an exemplary diagram illustrating a cross section taken along C1-C1′ line in FIG. 17, and FIG. 18B is an exemplary diagram illustrating a cross section taken along C2-C2′ line in FIG. 17.

The gas nozzle 20i illustrated in FIGS. 17 to 18B may be almost identical or similar to the gas nozzle 20h illustrated in FIG. 16, except that a tilting hole TP1i_H of a first tilting part TP1i and a tilting hole TP2i_H of a second tilting part TP2i are tilted opposite to each other. Accordingly, a difference from the gas nozzle 20h illustrated in FIG. 16 is mainly described.

According to one or more embodiments, a central axis TP1i_X of first tilting holes TP1i_H of the first tilting part TP1i may be misaligned by a positive angle relative to a central axis AXi of an alignment hole AHi. The positive angle may refer to a counterclockwise rotation angle when looking the gas nozzle 20i from outside. In addition, a central axis TP2i_X of second tilting holes TP2i_H of the second tilting part TP2i may be misaligned by a negative angle relative to the central axis AXi of the alignment hole AHi. The negative angle may refer to a clockwise rotation angle when looking the gas nozzle 20i from outside.

In FIG. 17, the tilting holes TP1i_H and TP2i_H of tilting parts TP1i and TP2i, similar to the tilting holes TH1, TH2, and TH3 illustrated in FIGS. 4 to 6C, are illustrated as having a linear difference between angles of the central axes TP1i_X and TP2i_X of the adjacent tilting holes TP1i_H and TP2i_H. However, according to one or more embodiments, a difference between the angles of the central axes TP1i_X and TP2i_X of tilting holes TP1i_H and TP2i_H may be nonlinear as illustrated in FIG. 7. In addition, according to one or more embodiments, the tilting holes TP1i_H and TP2i_H, as illustrated in FIGS. 8 to 9C, may have central axes sequentially spaced apart at an equal interval from the central axis AXi of the alignment hole AHi. In addition, according to one or more embodiments, the tilting holes TP1i_H and TP2i_H, as illustrated in FIG. 10, may have central axes sequentially spaced apart at a different interval from the central axis AXi of the alignment hole AHi.

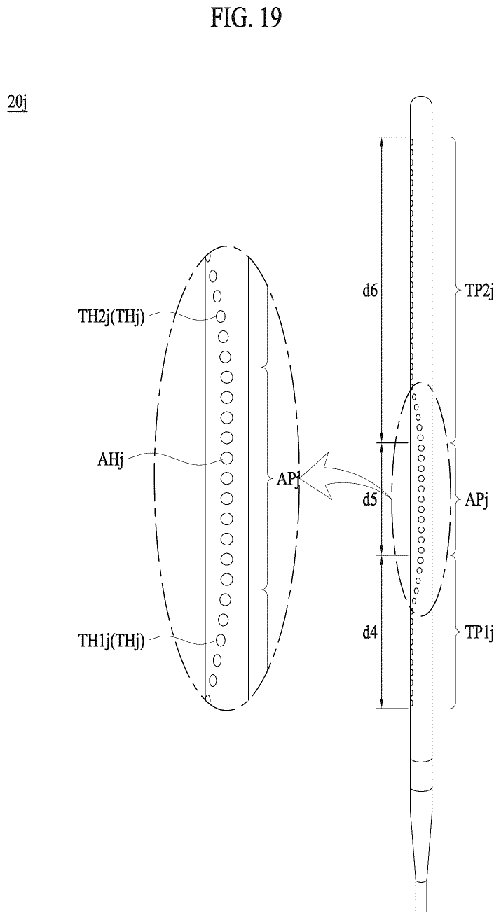

FIG. 19 is a schematic diagram illustrating a gas nozzle 20j according to one or more other embodiments.

The gas nozzle 20j illustrated in FIG. 19 may be almost identical or similar to the gas nozzle 20 illustrated in FIGS. 4 to 6C, except that an alignment part APj is singular, and tilting parts TP1j and TP2j are plural. The gas nozzle 20j illustrated in FIG. 19 may be almost identical or similar to the gas nozzle 20i illustrated in FIG. 17, except that lengths of the tilting parts TP1j and TP2j is longer than a length of the alignment part APj. Hereinafter, a difference from the gas nozzle 20 illustrated in FIGS. 4 to 6C is mainly described below.

Referring to FIG. 19, the gas nozzle 20j may be extended lengthwise along a longitudinal direction (the first direction D1). The gas nozzle 20j may include the alignment part APj, a first tilting part TP1j, and a second tilting part TP2j including a hole disposed at a position facing each of the plurality of wafers W along the longitudinal direction.

As illustrated in FIG. 19, the first tilting part TP1j may be positioned at a bottommost portion of the gas nozzle 20j, and the alignment part APj may be positioned in a middle of the gas nozzle 20j, and the second tilting part TP2j may be positioned at a topmost portion of the gas nozzle 20j.

According to one or more embodiments, the first tilting part TP1j may have a fourth length L4 along the first direction D1, and the alignment part APj may have a fifth length L5 along the first direction D1, and the second tilting part TP2j may have a sixth length L6 along the first direction D1. In FIG. 19, the sixth length L6 of the first tilting part TP2j is illustrated longer than the fifth length L5 of the alignment part APj and the fourth length L4 of the second tilting part TP1j. However, according to one or more embodiments, a magnitude relation between the fourth length L4 of the first tilting part TP1j, the fifth length L5 of the alignment part APj, and the sixth length L6 of the second tilting part TP2j may be different from what illustrated in FIG. 19. For example, the fifth length L5 of the alignment part APj may be shorter than at least one of the fourth length L4 of the first tilting part TP1j and the sixth length L6 of the second tilting part TP2j. The lengths of the first tilting part TP1j, the second tilting part TP2j, and the alignment part APj in the first direction D1 may be proportional to the number of holes formed in each area.

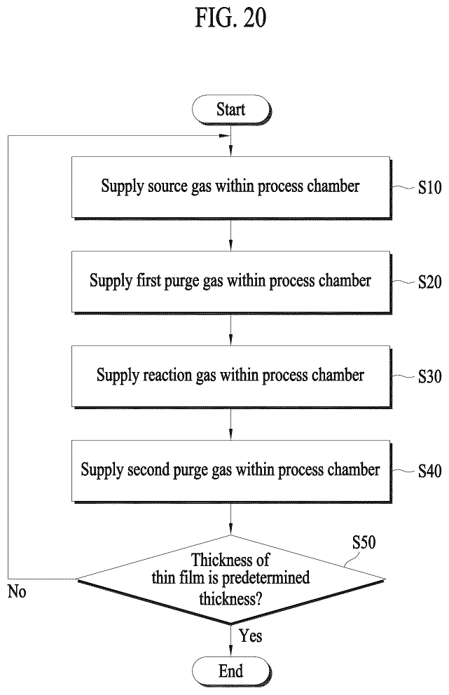

FIG. 20 is a flowchart illustrating a thin film deposition method using the wafer processing apparatus 1 according to one or more embodiments. For clearer understanding, FIGS. 1 to 6 are referred to together for description hereinafter.

In one or more embodiments, the process chamber 30 may be a chamber for performing the ALD process on the wafers W. The wafers W may be, for example, a silicon wafer or a germanium wafer.

The thin film deposition method using the wafer processing apparatus 1 according to one or more embodiments may first include wafers W within the process chamber 30. The wafer processing apparatus 1 may be semiconductor equipment of a batch type. The wafers W may be stacked along the first direction D1 (for example, a longitudinal direction of the process chamber) within the process chamber 30. Each of the plurality of wafers W may be positioned to correspond to a hole (for example, the alignment holes AH and the tilting holes TH) formed on the gas nozzle 20.

The thin film deposition method using the wafer processing apparatus 1 according to one or more embodiments may include operation S10 of supplying a source gas within the process chamber 30. The source gas may be charged in the charging tanks 148 and 168 connected to the gas supply pipes 40 and 60, and after forming a source gas having a pressure greater than a predetermined charging pressure within the charging tanks 148 and 168, the source gas may be supplied within the process chamber 30. The source gas charged in the charging tanks 148 and 168 may be delivered to the gas nozzle 20 through the gas supply pipes 40 and 60 and then sprayed on the wafers W through a plurality of the alignment holes AH and the tilting holes TH formed on the gas nozzle 20.

As the source gas may be sprayed on the wafers W, a precursor thin film may be formed on the wafers W. As the source gas, hexachlorodisilane (HCDS) gas, dichlorosilane (DCS) gas, or diisopropylaminosilane (DIPAS) gas may be used. However, a type of the source gas is not limited to those enumerated above, and the type of the source gas may vary depending on a type of an atomic layer to be formed on the wafers W.

The thin film deposition method using the wafer processing apparatus 1 according to one or more embodiments may include operation S20 of supplying a first purge gas within the process chamber 30.

The first purge gas may be supplied through the gas nozzle 20 installed within the process chamber 30 or another purge gas supplier. When the first purge gas is supplied within the process chamber 30, an exhaust system may be formed within the wafer processing apparatus 1 as the exhaust pipe 80 is activated. As the first purge gas is sprayed on the wafers W, a first reaction gas not chemically adsorbed to the wafers W but lingering may be purged. The first purge gas may include, for example, argon (Ar).

The thin film deposition method using the wafer processing apparatus 1 according to one or more embodiments may include operation S30 of supplying a reaction gas within the process chamber 30.

The reaction gas may be charged in the charging tanks 148 and 168 connected to the gas supply pipes 40 and 60, and after forming a reaction gas having a pressure greater than a predetermined charging pressure in the charging tanks 148 and 168, the reaction gas may be supplied within the process chamber 30. The reaction gas charged in the charging tanks 148 and 168 may be delivered to the gas nozzle 20 through the gas supply pipes 40 and 60 and then sprayed on the wafers W through the alignment holes AH and the tilting holes TH formed on the gas nozzle 20.

The precursor thin film formed on the wafers W, as the reaction gas is sprayed on the wafers W, may be transformed into a metal film. The reaction gas may include, for example, diborane (B₂H₆), disilane (Si₂H₆), silane (SiH₄), and hydrogen (H₂). However, a type of the reaction gas is not limited to those enumerated above but may vary depending on a type of an atomic layer to be formed on the wafers W.

The thin film deposition method using the wafer processing apparatus 1 according to one or more embodiments may include operation S40 of supplying a second purge gas within the process chamber 30.

The second purge gas may be supplied through the gas nozzle 20 installed within the process chamber 30 or another purge gas supplier. Through the second purge gas, a residue within the process chamber 30 may be discharged.

The thin film deposition method using the wafer processing apparatus 1 according to one or more embodiments may include operation S50 of identifying whether a thickness of the metal film has a predetermined thickness. Subsequently, when the thickness of the formed metal film reaches the predetermined thickness, the thin film deposition method using the wafer processing apparatus 1 may end. When the thickness of the formed metal film does not reach the predetermined thickness, the operation S10 to operation S40 may be performed again after going back to operation S10.

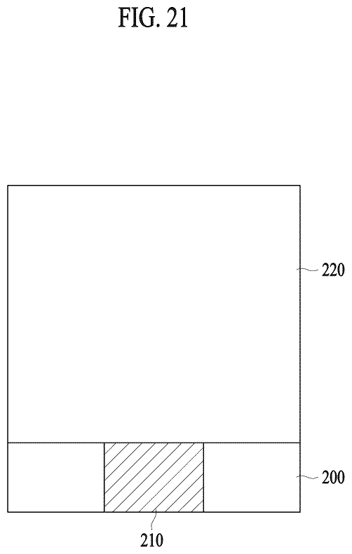

FIGS. 21 to 25 are cross-sectional views illustrated according to a process sequence for explaining a process of manufacturing a semiconductor device through a thin film deposition method using a wafer processing apparatus according to one or more embodiments.

For example, FIGS. 21 to 25 illustrate a method of forming a conductive structure of a semiconductor device using the aforementioned thin film deposition method according to one or more embodiments.

Referring to FIG. 21, an interlayer insulation layer 220 may be formed on a substructure 200 including a conductive pattern 210. In one or more embodiments, the substructure 200 may include, for example, a sub insulation layer formed on the wafers W illustrated in FIG. 1 (hereinafter referring to FIG. 1). On the wafers W, a circuit element including a word line, a gate structure, a diode, a source/drain layer, a contact, and a wiring may be formed.

In this case, the substructure 200 may be formed on the wafers W to be provided on and/or cover the circuit element. The conductive pattern 210 may be formed within the substructure 200 and provided as a plug electrically connected to at least a portion of the circuit element. The substructure 200 may be formed through, for example, a chemical vapor deposition (CVD) process, to include a silicon oxide-based material. The conductive pattern 210 may be formed to include a metal such as tungsten (W), copper (Cu), titanium (Ti), and tantalum (Ta), and metal nitride, metal silicide, and/or doped polysilicon.

In one or more embodiments, the substructure 200 may include a semiconductor substrate. For example, the substructure 200 may include silicon, germanium, silicon-germanium, or a group of III-V compound such as gallium phosphide (GaP), gallium arsenide (GaAs), and gallium antimonide (GaSb). According to one or more embodiments, the substructure 200 may be a silicon-on-insulator (SOI) substrate or a germanium-on-insulator (GOI) substrate. In this case, the conductive pattern 210 may be an n-type or a p-type impurity region formed within the substructure 200. The interlayer insulation layer 220 may be formed to include a silicon oxide-based material or a low dielectric organic oxide. For example, the interlayer insulation layer 220 may be formed through the CVD process or a spin coating process.

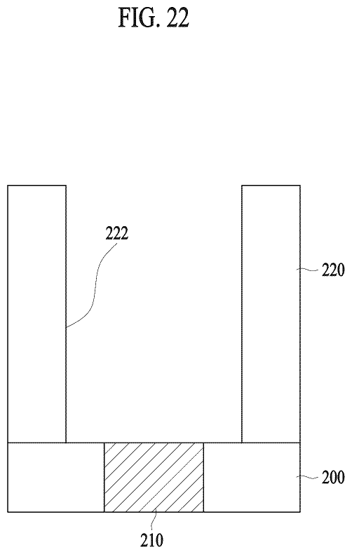

Referring to FIG. 22, an opening portion 222 that at least partially exposes the conductive pattern 210 by partially removing the interlayer insulation layer 220 may be formed. In one or more embodiments, the opening portion 222 may have a hole shape that completely exposes a top surface of the conductive pattern 210. In one or more embodiments, the opening portion 222 may have a trench shape that is linearly extended while exposing the top surface of the conductive pattern 210.

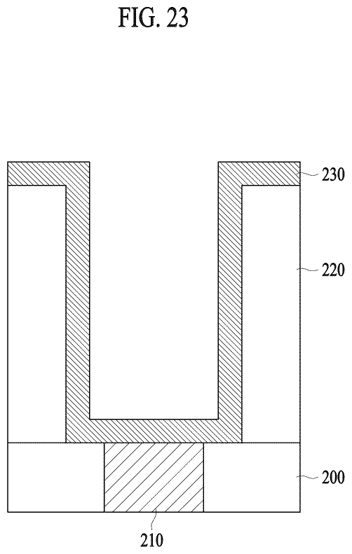

Referring to FIG. 23, a barrier conductive layer 230 may be formed along a surface of the interlayer insulation layer 220 and a sidewall and a bottom surface of the opening portion 222.

According to one or more embodiments, the barrier conductive layer 230 may be formed by using an organometallic precursor and by using the ALD process or a plasma enhanced atomic layer deposition (PEALD) process. For example, the barrier conductive layer 230 may be formed to include tungsten nitride, tungsten carbide, or tungsten carbonitride. In one or more embodiments, the barrier conductive layer 230 may be formed by using the thin film deposition method described with reference to FIG. 23. As described with reference to FIG. 23, a metal layer of a predetermined thickness may be formed by repeatedly performing a deposition cycle including a source gas supplying process, a first purging process, a reaction gas supplying process, and a second purging process.

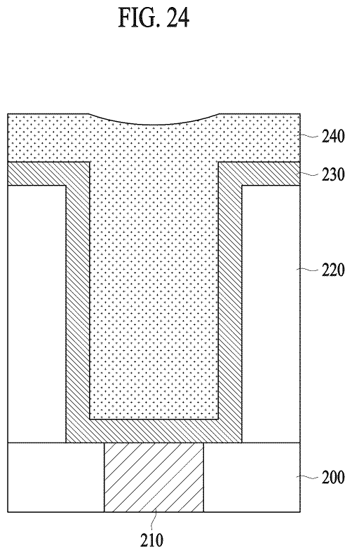

Referring to FIG. 24, a metal layer 240 may be formed on the barrier conductive layer 230 to fill the opening portion 222 enough.

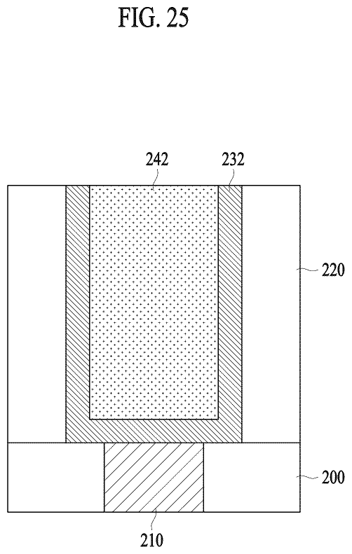

Referring to FIG. 25, a top of the metal layer 242 and the barrier conductive layer 232 may be planarized until a top surface of the interlayer insulation layer 220 is exposed through, for example, a chemical mechanical polishing (CMP) process.

In one or more embodiments, a conductive structure electrically connected to the conductive pattern 210 and including a barrier conductive pattern 232 and a metal filling pattern 242 may be formed within the opening portion 222 by the planarization process. According to one or more embodiments, the conductive structure may include, for example, a tungsten nitride/tungsten (WNx/W) stacked structure.

In one or more embodiments, after the barrier conductive layer 230 is formed, a pre-treatment process may be formed. The pre-treatment process may be formed by using a reaction gas process of the thin film deposition method described with reference to FIG. 20

For example, diborane (B₂H₆) may be supplied as a reaction gas on the wafers W where the barrier conductive layer 230 is formed. The reaction gas may be supplied by using a reaction gas supplier having a multi charging tank or a pressurized charging tank to form a nucleation layer. The diborane (B₂H₆) reaction gas decomposes on a substrate surface and is absorbed as single boron or various boron hydride to help quick nucleation of a tungsten thin film.

While embodiments have been described with reference to the figures, it will be understood by those of ordinary skill in the art that various changes in form and details may be made therein without departing from the spirit and scope as defined by the following claims and their equivalents.

What is claimed is:

1. A wafer processing apparatus comprising:
a process chamber configured to comprise a plurality of wafers stacked in a first direction; and
a gas nozzle included in the process chamber, the gas nozzle extending along the first direction,
wherein the gas nozzle comprises an alignment hole and a tilting hole, the alignment hole and the tilting hole being configured to face the plurality of wafers along the first direction based on the plurality of wafers being stacked in the process chamber in the first direction,
wherein a central axis of the alignment hole is configured to pass through a central axis of the plurality of wafers based on the plurality of wafers being stacked in the process chamber in the first direction, and
wherein a central axis of the tilting hole is configured to be misaligned with respect to the central axis of the plurality of wafers.

2. The wafer processing apparatus of claim 1, wherein the tilting hole comprises:
a first tilting hole having a first central axis misaligned by a first angle from the central axis of the alignment hole;
a second tilting hole having a second central axis misaligned by a second angle, that is greater than the first angle, from the central axis of the ; and
a third tilting hole having a third central axis misaligned by a third angle, that is greater than the second angle, from the central axis of the.

3. The wafer processing apparatus of claim 2, wherein a difference between the first angle and the second angle is equal to a difference between the second angle and the third angle.

4. The wafer processing apparatus of claim 2, wherein a difference between the first angle and the second angle is less than a difference between the second angle and the third angle.

5. The wafer processing apparatus of claim 1, wherein a diameter of the alignment hole and a diameter of the tilting hole are equal.

6. The wafer processing apparatus of claim 1, wherein the tilting hole comprises a plurality of tilting holes that are spaced apart at an equal interval from each other along the first direction.

7. The wafer processing apparatus of claim 1, wherein the tilting hole comprises:
a plurality of first tilting holes having a first central axis misaligned by a first angle from the central axis of the alignment hole and arranged along the first direction;
a plurality of second tilting holes having a second central axis misaligned by a second angle, that is greater than the first angle, from the central axis of the alignment hole and arranged along the first direction; and
a plurality of third tilting holes having a third central axis misaligned by a third angle, that is greater than the second angle, from the central axis of the alignment hole and arranged along the first direction.

8. The wafer processing apparatus of claim 7, wherein a difference between the first angle and the second angle is equal to a difference between the second angle and the third angle.

9. The wafer processing apparatus of claim 7, wherein a difference between the first angle and the second angle is smaller than a difference between the second angle and the third angle.

10. The wafer processing apparatus of claim 1,
wherein the tilting hole comprises:
a first tilting hole having a first central axis parallel to the central axis of the alignment hole and spaced apart from the central axis of the alignment hole by a first distance in a second direction that crosses the first direction;
a second tilting hole having a second central axis parallel to the central axis of the alignment hole and spaced apart by a second distance from the central axis of the alignment hole, the second distance being greater than the first distance in the second direction; and
a third tilting hole having a third central axis parallel to the central axis of the alignment hole and spaced apart by a third distance from the central axis of the alignment hole, the third distance being greater than the second distance in the second direction.

11. The wafer processing apparatus of claim 10, wherein a difference between the first distance and the second distance is equal to a difference between the second distance and the third distance.

12. The wafer processing apparatus of claim 10, wherein a difference between the first distance and the second distance is less than a difference between the second distance and the third distance.

13. A wafer processing apparatus, comprising:
a process chamber configured to comprise a plurality of wafers stacked in a first direction;
a gas supply pipe configured to supply a reaction gas into the process chamber; and
a gas nozzle included in the process chamber and extending along the first direction, the gas nozzle being configured to spray the plurality of wafers with the reaction gas supplied from the gas supply pipe based on the plurality of wafers being stacked in the process chamber in the first direction,
wherein the gas nozzle comprises an alignment part, a first tilting part, and a second tilting part,
wherein the alignment part comprises a plurality of alignment holes being configured to face the plurality of wafers along the first direction and respectively having a central axis being configured to pass through a central axis of the plurality of wafers based on the plurality of wafers being stacked in the process chamber in the first direction,
wherein the first tilting part comprises a plurality of first tilting holes being configured to face the plurality of wafers along the first direction and respectively having a central axis being configured to be spaced apart from the central axis of the plurality of wafers based on the plurality of wafers being stacked in the process chamber in the first direction, and
wherein the second tilting part is spaced apart from the first tilting part in the first direction and comprises a plurality of second tilting holes being configured to face the plurality of wafers along the first direction and respectively having a central axis being configured to be spaced apart from the central axis of the plurality of wafers based on the plurality of wafers being stacked in the process chamber in the first direction.

14. The wafer processing apparatus of claim 13, wherein the first tilting part is at a bottommost portion of the gas nozzle and the second tilting part is at a topmost portion of the gas nozzle in the first direction.

15. The wafer processing apparatus of claim 14, wherein the alignment part is between the first tilting part and the second tilting part in the first direction.

16. The wafer processing apparatus of claim 14, wherein a length of the alignment part in the first direction is less than at least one of a length of the first tilting part along the first direction and a length of the second tilting part along the first direction.

17. The wafer processing apparatus of claim 13, wherein the plurality of alignment holes are spaced apart at an equal interval from each other along the first direction,
wherein the plurality of first tilting holes are spaced apart at an equal interval from each other along the first direction, and
wherein the plurality of second tilting holes are spaced apart at an equal interval from each other along the first direction.

18. The wafer processing apparatus of claim 13, wherein the plurality of first tilting holes respectively has a central axis misaligned by a positive angle relative to the central axis of the plurality of alignment holes, and
wherein the plurality of second tilting holes respectively has a central axis misaligned by a negative angle relative to the central axis of the plurality of alignment holes.

19. A wafer processing apparatus comprising:
a process chamber configured to comprise a plurality of wafers stacked in a first direction;
a gas supply pipe configured to supply a reaction gas into the process chamber; and
a gas nozzle included in the process chamber and extending along the first direction, the gas nozzle being configured to spray the plurality of wafers with the reaction gas supplied from the gas supply pipe based on the plurality of wafers being stacked in the process chamber in the first direction,
wherein the gas nozzle comprises a first alignment part, a second alignment part, and a tilting part,
wherein the first alignment part comprises a plurality of first alignment holes being configured to face the plurality of wafers along the first direction and respectively having a central axis being configured to pass through a central axis of the plurality of wafers based on the plurality of wafers being stacked in the process chamber in the first direction,
wherein the second alignment part comprises a plurality of second alignment holes being configured to face the plurality of wafers along the first direction and respectively having a central axis being configured to pass through the central axis of the plurality of wafers based on the plurality of wafers being stacked in the process chamber in the first direction,
wherein the tilting part comprises a plurality of tilting holes being configured to face the plurality of wafers along the first direction and respectively having a central axis being configured to be spaced apart from the central axis of the plurality of wafers based on the plurality of wafers being stacked in the process chamber in the first direction, and
wherein the tilting part is between the first alignment part and the second alignment part along the first direction.

20. The wafer processing apparatus of claim 19, wherein the first alignment part is at an lower portion of the gas nozzle and the second alignment part is at a upper portion of the gas nozzle in the first direction, and
wherein a length of the second alignment part in the first direction is greater than a length of the first alignment part in the first direction.
